(19) United States
(12) Patent Application Publication
(10) Pub. No.: US 2009/0046420 A1
(43) Pub. Date: Feb. 19, 2009

(54) APPARATUS, SYSTEM, AND METHOD FOR ATTENUATING VIBRATION

(76) Inventors: Armando Jesus Argumedo, Tucson, AZ (US); Edwin Ralph Childers, Tucson, AZ (US); Reed Alan Hancock, Tucson, AZ (US); Kevin Bruce Judd, Tucson, AZ (US)

Correspondence Address: Kunzler & McKenzie, 8 EAST BROADWAY, SUITE 600, SALT LAKE CITY, UT, 84111, US

(21) Appl. No.: 11/839,456

(22) Filed: Aug. 15, 2007

(51) Int. Cl. G06F 1/16; A47B 81/00; H05K 5/00; H05K 7/00; A47B 97/00

(52) U.S. Cl. 361/685; 312/223.2

(57) ABSTRACT

An apparatus, system, and method are disclosed for attenuating vibration. A cover includes at least four slots. Each slot physically isolates a midsection from either the distal end or the proximal end of the cover. In one embodiment, a first slit isolates a midsection side and a second slit at an angle in the range of seventy degrees to one hundred-ten degrees to the first slit physically isolates a portion of a top from a portion of a side. The midsection is physically connected to an enclosure configured to supply power, cooling, and communications to the storage mechanism.

### BACKGROUND OF THE INVENTION

1. Field of the Invention

This invention relates to attenuating vibration and more particularly relates to attenuating vibration in a storage mechanism.

2. Description of the Related Art

Storage mechanisms such as magnetic tape drives, hard disk drives, optical storage mechanisms, holographic storage mechanisms, micromechanical storage mechanisms, and the like often function in an environment with mechanical vibration. For example, a storage mechanism may be mounted in an enclosure with a cooling fan and other devices that generate vibration. Similarly, adjacent enclosures may transmit vibration to the storage mechanism.

Storage mechanisms typically must precisely position a read/write device such as a read head and/or a write head relative to the storage medium. For example, a magnetic tape drive read/write head may be positioned relative to a magnetic tape, with some tolerances equivalent to a few microns. Vibration may disturb the spatial positioning of the read/write device and the storage medium, causing read and/or write failures.

### SUMMARY OF THE INVENTION

From the foregoing discussion, there is a need for an apparatus, system, and method that attenuates vibration. Beneficially, such an apparatus, system, and method would enable attenuation of vibration.

The present invention has been developed in response to the present state of the art, and in particular, in response to the problems and needs in the art that have not yet been fully solved by currently available vibration attenuation systems. Accordingly, the present invention has been developed to provide an apparatus, system, and method for attenuating vibration that overcome many or all of the above-discussed shortcomings in the art.

The apparatus to attenuate vibration is provided with a plurality of modules configured to functionally execute the steps of mounting a storage mechanism in physical communication with a cover, physically isolating the midsection from the mounting elements with the slots, and physically connecting the midsection to an enclosure configured to supply power, cooling, and communications to the storage mechanism. These modules in the described embodiments include a storage mechanism and a cover.

The storage mechanism retains a removable storage medium in a retention position, writes encoded data to the removable storage medium, and reads encoded data from the removable storage medium. The cover is arranged in physical communication with the storage mechanism. The cover comprises a distal end, a proximal end and a midsection between the distal end and the proximal end.

The storage medium is inserted into the retention position at the proximal end. A plurality of mounting elements are arranged to mount the cover to the storage mechanism. Two mounting elements are disposed near the proximal end and two mounting elements are disposed near the distal end, and four slots substantially physically isolate the midsection from the mounting elements.

In one embodiment the cover comprises of an upper planar member extending from the distal end to the proximal end and a first and second side planar members each extending from the distal end to the proximal end in physical communication with the top and disposed at an angle in the range of seventy degrees to one hundred-ten degrees (70°-110°) to the top.

In another embodiment each slot comprises a first slit that physically separates a midsection side from an end. A second slit is arranged at an angle in the range of seventy degrees to one hundred-ten degrees (70°-110°) to the first slit and that physically separates a portion of the top from a portion of a side. Each second slit runs from the first slit toward the midsection.

The removable storage medium may be disposed within a cassette. In one embodiment, the removable storage medium is a magnetic tape. The mounting elements are configured as mounting holes that accept a fastener that physically connects the cover to the storage mechanism. The mounting holes are threaded and accept a screw.

The tape drive is mounted using threaded holes in the cover. If the cover is stiff, then the external vibration is translated directly to the deck, which contains the tape path and read/write head. This can cause problems in keeping the relative motion of the tape and head small. If the cover is modified such that it is flexible, then the deck (with the tape path and read/write head) will be somewhat isolated from the external vibrations. This allows the drive to operate normally in environments with higher vibration levels.

The system to attenuate vibration includes a storage mechanism, an enclosure and a cover. The storage mechanism is configured to retain a removable storage medium in a retention position, write encoded data to the removable storage medium, and read encoded data from the removable storage medium. The enclosure is configured to supply power, cooling and communications to the storage mechanism.

The cover is arranged in physical communication with the storage mechanism and comprising a distal end, a proximal end wherein the storage medium is inserted into the retention position at the proximal end and a midsection between the distal end and the proximal end. A plurality of mounting elements configured to mount the cover to the storage mechanism, wherein at least two mounting elements are disposed near the proximal end and at least two mounting elements are disposed near the distal end.

The cover includes at least four slots that substantially physically isolate the midsection from the mounting elements and a plurality of midsection mounting elements that physically connect the midsection to the enclosure.

A method for attenuating vibration is also presented. The method in the disclosed embodiments substantially includes the steps to carry out the functions presented above with respect to the operation of the described apparatus and system. The method comprises mounting a storage mechanism in physical communication with a cover, physically isolating the midsection from the mounting elements with the slots, and physically connecting the midsection to an enclosure configured to supply power, cooling, and communications to the storage mechanism.

The storage mechanism is mounted in physical communication with the cover. The storage mechanism is configured to retain a removable storage medium in a retention position, write encoded data to the removable storage medium, and read encoded data from the removable storage medium.

The cover comprises a distal end, a proximal end and a midsection between the distal end and the proximal end. The storage medium is inserted into the retention position at the proximal end. A plurality of mounting elements are configured to mount the cover to the storage mechanism, wherein at least two mounting element are disposed near the proximal end and at least two mounting elements are disposed near the distal end.

The cover further comprises a top configured as planar member extending from the distal end to the proximal end and a first and second side each extending from the distal end to the proximal end and configured as planar members in physical communication with the top and disposed at an angle in the range of seventy degrees to one hundred-ten degrees degrees (70°-110°) to the top.

The cover includes at least four slots. Each slot physically isolates the midsection from either the distal end and/or the proximal end. In one embodiment, a first slit isolates the midsection side and a second slit at an angle in the range of seventy degrees to one hundred-ten degrees to the first slit physically separates the a portion of the top from a portion of a midsection side.

In one embodiment the mounting elements may be configured as mounting holes that accept a fastener that physically connects the cover to the storage mechanism. The mounting holes may be threaded and accept a screw.

The slots physically isolate the midsection from the mounting elements. In one embodiment, midsection mounting elements physically connect the midsection to an enclosure configured to supply power, cooling, and communications to the storage mechanism.

References throughout this specification to features, advantages, or similar language do not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments of the invention.

This invention uses a drive cover as a way to attenuate the external vibration. The advantage is that it allows for vibration attenuation without taking up the space that shock mounts need. These features and advantages of the present invention will become more fully apparent from the following description and appended claims, or may be learned by the practice of the invention as set forth hereinafter.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1A is a perspective drawing illustrating one embodiment of a vibration attenuation apparatus in accordance with the present invention;

FIG. 1B is a perspective drawing illustrating one embodiment of an enclosure in accordance with the present invention;

FIG. 2 is a perspective drawing illustrating one embodiment of a cover of the present invention;

FIG. 3 is a drawing illustrating a side elevation of one embodiment of a cover of the present invention;

FIG. 4 is a schematic flow chart diagram illustrating one embodiment of a vibration attenuation method of the present invention; and

FIG. 5 is a graph showing an improvement in drive performance using the vibration attenuation apparatus of the present invention;

### DETAILED DESCRIPTION OF THE INVENTION

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. One skilled in the relevant art will recognize, however, that the invention may be without one or more of the specific details, or with other methods, components, materials, and so forth. In other instances, well-known structures, materials, or operations are not shown or described in detail to avoid obscuring aspects of the invention.

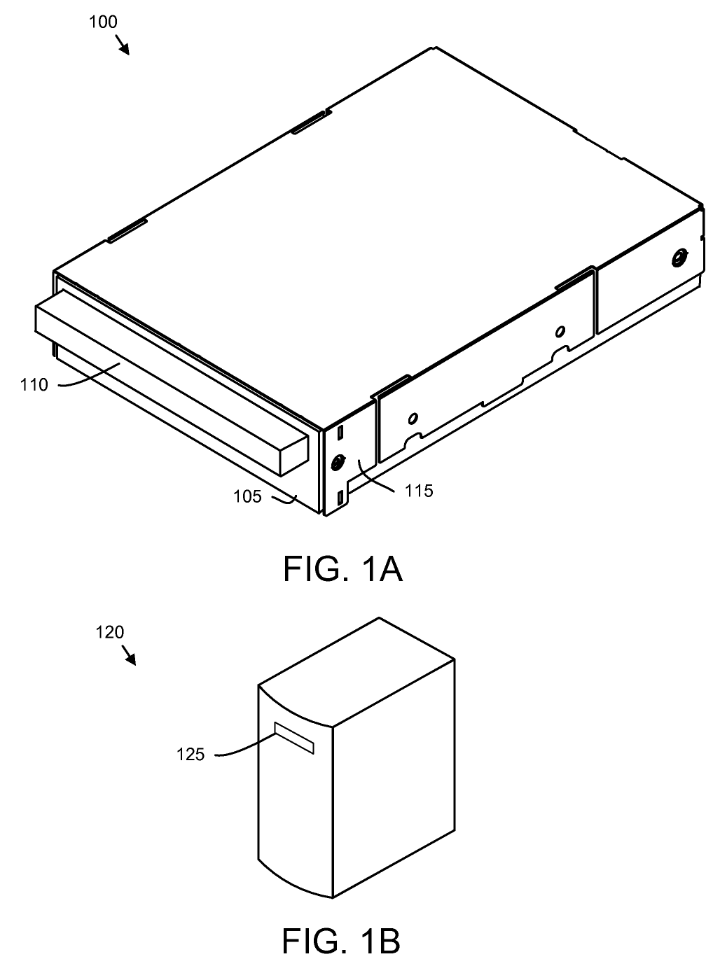

FIG. 1A is a perspective drawing illustrating one embodiment of a vibration attenuation apparatus 100 in accordance with the present invention. The apparatus 100 includes a storage mechanism 105, a cover 115, and a storage medium 110. The storage mechanism 105 is configured in physical communication with the cover 115. The storage mechanism 105 retains the removable storage medium 110 in a retention position. In addition, the storage mechanism 105 writes encoded data to the removable storage medium 110 and reads encoded data from the removable storage medium 110.

The removable storage medium 110 may be disposed within a cassette. In one embodiment, the removable storage medium 110 is a magnetic tape. In an alternate embodiment, the removable storage medium 110 may include an optical storage medium, a holographic storage medium, and/or a micromechanical storage medium.

FIG. 1B is a perspective drawing illustrating one embodiment of an enclosure 120 in accordance with the present invention. The enclosure 120 is configured to supply power, cooling, and communications to the storage mechanism 105. The enclosure 120 120 includes an access port 125 to enable access to the storage mechanism 105.

Storage mechanisms such as magnetic tape drives, hard disk drives, optical storage mechanisms, holographic storage mechanisms, micromechanical storage mechanisms, and the like often function in an environment with mechanical vibration. For example, a storage mechanism may be mounted in an enclosure with a cooling fan and other devices that generate vibration. Similarly, adjacent enclosures may transmit vibration to the storage mechanism. Hence the need arises to isolate the storage mechanism 105 from the vibration of the enclosure 120.

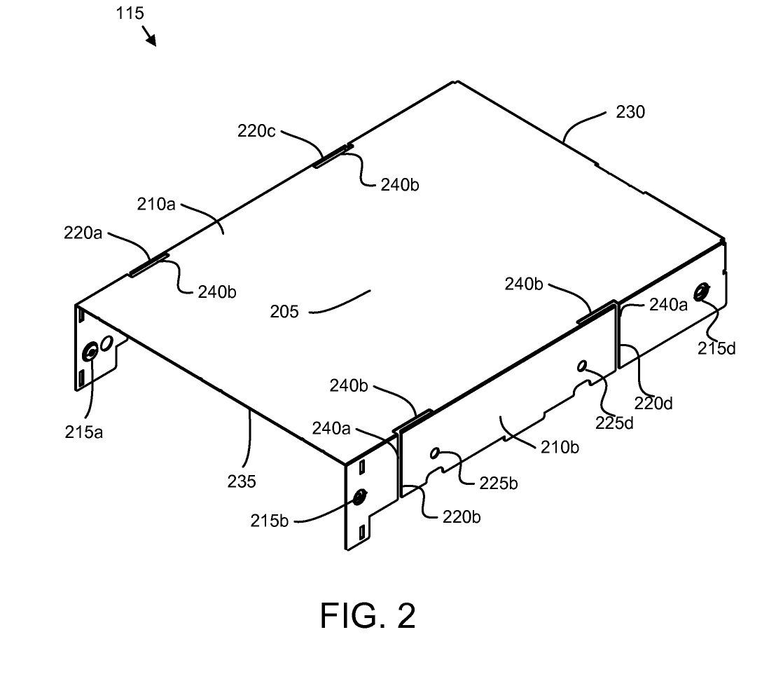

FIG. 2 is a perspective drawing illustrating one embodiment of a cover 115 of the present invention. The cover 115 is the cover 115 of FIG. 1. The description of the cover 115 refers to elements of FIG. 1, like numbers referring to like elements. The cover 115 comprises a distal end 230, a proximal end 235, and a midsection 210 between the distal end 230 and the proximal end 235.

The storage medium 110 is inserted into the retention position at the proximal end 235. A plurality of mounting elements 215a, 215b, 215c, 215d are arranged to mount the cover 115 to the storage mechanism 105. First and second mounting elements 215a, 215b are disposed near the proximal end 235 and third and fourth mounting elements 215c (not shown) and 215d are disposed near the distal end 230.

In one embodiment the cover 115 comprises of an upper planar member 205 extending from the distal end 230 to the proximal end 235 and a first and second side planar members 210a, 210b each extending from the distal end 230 to the proximal end 235 in physical communication with the top and disposed at an angle in the range of seventy degrees to one hundred-ten degrees (70°-110°) to the top.

In one embodiment, the cover 115 is formed of a plastic material. For example, the cover 115 may be obtained by injection molding transparent plastic, thermoplastic resin, or a thermoplastic elastomeric material. The mold container should be made in such a way that the cover 115 is made as a one-piece injection molded part.

In one embodiment, the cover 115 is formed of stamped metal. A punch may cut the cover 115 from a sheet of metal using a pattern. The punch may further cut the slots 220, holes such as for the mounting elements 215.

In another embodiment each slot 220a, 220b, 220c and 220d comprises a first slit 240a that physically separates a midsection side 210 from an end. A second slit 240b may be arranged at an angle in the range of seventy degrees to one hundred-ten degrees (70°-110°) to the first slit 240a and that physically separates a portion of the top from a portion of a side. Each second slit 240b runs from the first slit toward the midsection 210.

The mounting elements 215a, 215b, 215c and 215d are configured as mounting holes that accept a fastener that physically connects the cover 115 to the storage mechanism 105. The mounting holes may be threaded and accept a screw. In one embodiment the mounting elements 215a-d may be configured as grooves (slots) for receiving the tongue (deep ridge) that may be provided on the storage mechanism 105. In another embodiment the mounting elements 215a-d may be configured as predrilled holes to accept a rivet. As is known to one skilled in the art, a rivet may be placed in the predrilled hole. The rivet may be upset so the shaft fills the hole and the tail expands to one point five (1.5) times the original shaft diameter and holds the rivet in place. The mounting elements 215a-d may also be configured as interlocking elements provided on the cover 115 and the storage mechanism 105.

In one embodiment the cover 115 includes midsection mounting elements 225a-d configured as mounting holes that accept a fastener to physically connect the midsection 210 of the cover 115 to the enclosure 120. The mounting holes may be threaded and accept a screw. In one embodiment the midsection mounting elements 225a-d may be configured as grooves (slots) for receiving the tongue (deep ridge) that may be provided on the enclosure 120.

In another embodiment the midsection mounting elements 225a-d may be configured as predrilled holes to accept a rivet. The midsection mounting elements 225a-d may also be configured as interlocking elements provided on the cover 115 and the storage mechanism 105.

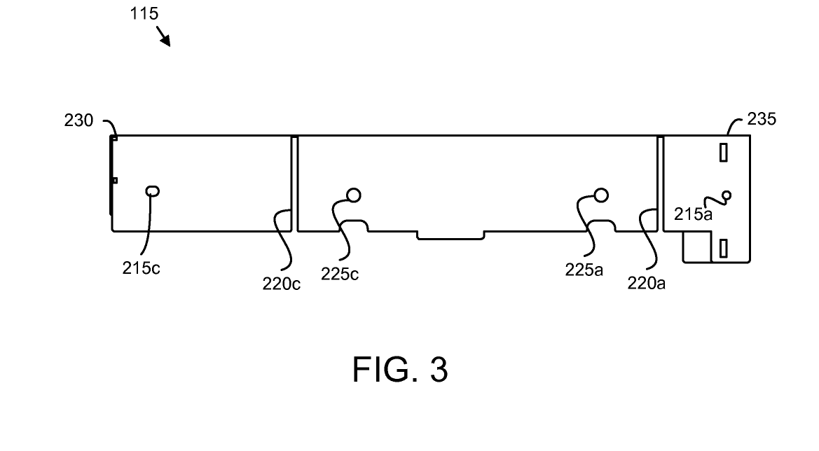

FIG. 3 is a drawing illustrating a side elevation of one embodiment of a cover of the present invention. The elements of the cover 115 are elements of FIGS. 1 and 2, like numbers referring to like elements.

The schematic flow chart diagram that follows is generally set forth as a logical flow chart diagram. As such, the depicted order and labeled steps are indicative of one embodiment of the presented method. Other steps and methods may be conceived that are equivalent in function, logic, or effect to one or more steps, or portions thereof, of the illustrated method. Additionally, the format and the symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

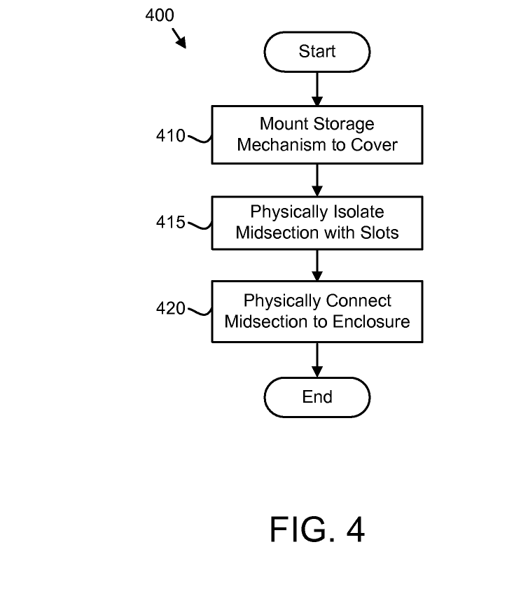

FIG. 4 is a schematic flow chart diagram illustrating one embodiment of a vibration attenuation method 400 of the present invention. The method 400 in the disclosed embodiments substantially includes the steps to carry out the functions presented above with respect to the operation of the described apparatus and system of FIGS. 1-3. The method 400 refers to elements of FIGS. 1-3, like numbers referring to like elements.

The method 400 begins and a storage mechanism 105 is mounted 410 in physical communication with a cover 115. The cover 115 includes at least four slots 220. Slots 220 physically isolate 415 the upper planar member 205 from either the distal end 230 or the proximal end 235. In one embodiment, a first slit 240a isolates the midsection side 210 210 and a second slit 240b at an angle in the range of seventy degrees to one hundred-ten degrees (70°-110°) to the first slit 240a physically isolates 415 the portion of the top upper planar member 205 from a portion of a midsection side 210. The upper planar member 205 is physically connected 420 to an enclosure 120 configured to supply power, cooling, and communications to the storage mechanism 105.

Typically, the storage mechanism 105 is mounted 410 using threaded holes in the cover 115. If the cover 115 is stiff, then the external vibration is translated directly to the storage mechanism 105, which may contain a tape path and a read/write head. This can cause problems in keeping the relative motion of the tape and head small. In the present invention the cover 115 is modified such that it is flexible, hence the storage mechanism 105 (with the tape path and read/write head) is isolated from the external vibrations. This allows the apparatus to operate normally in environments with higher vibration levels.

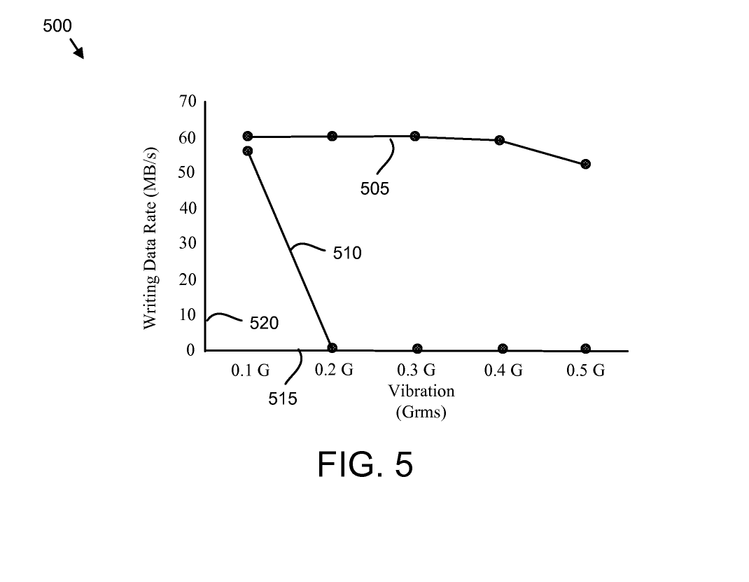

FIG. 5 is a graph 500 showing an improvement in drive performance using the vibration attenuation apparatus of the present invention. In actual test data taken with both standard covers and modified covers 115 of the present invention, a significant improvement in drive performance was observed in a vibration environment. The graph 500 shows the vibration in gravities root mean squared (Grms) on the X axis 515 and the writing data rate in megabytes per second (MB/s) on the Y axis 520. A standard line 510 shows that with a standard cover 115, the storage mechanism 105 cannot write at vibration levels of zero point two gravities root mean squared (0.2 Grms) and above. Whereas a modified line 505 shows that with the modified cover 115, a drive would function successfully to vibration levels of zero point five gravities root mean squared (0.5 Grms). These improvements were due to cover change alone.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus to attenuate vibration, the apparatus comprising:
a storage mechanism configured to retain a removable storage medium in a retention position, write encoded data to the removable storage medium, and read encoded data from the removable storage medium; and
a cover in physical communication with the storage mechanism and comprising a distal end, a proximal end wherein the storage medium is inserted into the retention position at the proximal end, a midsection between the distal end and the proximal end, a plurality of mounting elements configured to mount the cover to the storage mechanism, wherein at least two mounting element are disposed near the proximal end and at least two mounting elements are disposed near the distal end, and at least four slots that substantially physically isolate the midsection from the mounting elements.

2. The apparatus of claim 1, the cover further comprising a top configured as planar member extending from the distal end to the proximal end and a first and second side each extending from the distal end to the proximal end and configured as planar members in physical communication with the top and disposed at an angle in the range of seventy degrees to one hundred-ten degrees to the top.

3. The apparatus of claim 2, wherein each slot comprises a first slit that physically separates a midsection side from an end and a second slit at an angle in the range of seventy degrees to one hundred-ten degrees to the first slit and that physically separates the a portion of the top from a portion of a side.

4. The apparatus of claim 3, wherein each second slit runs from the first slit toward the midsection.

5. The apparatus of claim 1, wherein the removable storage medium is disposed within a cassette.

6. The apparatus of claim 1, wherein the removable storage medium is configured as a magnetic tape.

7. The apparatus of claim 1, wherein the mounting elements are configured as mounting holes that accept a fastener that physically connects the cover to the storage mechanism.

8. The apparatus of claim 7, wherein the mounting holes are threaded and accept a screw.

9. The apparatus of claim 1, further comprising a plurality of midsection mounting elements that physically connect the midsection to an enclosure.

10. A system to attenuate vibration, the system comprising:
a storage mechanism configured to retain a removable storage medium in a retention position, write encoded data to the removable storage medium, and read encoded data from the removable storage medium;
an enclosure configured to supply power, cooling, and communications to the storage mechanism; and
a cover in physical communication with the storage mechanism and comprising a distal end, a proximal end wherein the storage medium is inserted into the retention position at the proximal end, a midsection between the distal end and the proximal end, a plurality of mounting elements configured to mount the cover to the storage mechanism, wherein at least two mounting element are disposed near the proximal end and at least two mounting elements are disposed near the distal end, at least four slots that substantially physically isolate the midsection from the mounting elements and a plurality of midsection mounting elements that physically connect the midsection to the enclosure.

11. The system of claim 10, the cover further comprising a top configured as planar member extending from the distal end to the proximal end and a first and second side each extending from the distal end to the proximal end and configured as planar members in physical communication with the top and disposed at an angle in the range of seventy degrees to one hundred-ten degrees to the top.

12. The system of claim 11, wherein each slot comprises a first slit that physically separates a midsection side from an end and a second slit at an angle in the range of seventy degrees to one hundred-ten degrees to the first slit and that physically separates the a portion of the top from a portion of a side.

13. The system of claim 12, wherein each second slit runs from the first slit toward the midsection.

14. The system of claim 10, wherein the removable storage medium is disposed within a cassette.

15. The system of claim 10, wherein the removable storage medium is configured as a magnetic tape.

16. The system of claim 10, wherein the mounting elements are configured as mounting holes that accept a fastener that physically connects the cover to the storage mechanism.

17. The system of claim 16, wherein the mounting holes are threaded and accept a screw.

18. A method for attenuating vibration, the method comprising:
mounting a storage mechanism in physical communication with a cover, the storage mechanism configured to retain a removable storage medium in a retention position, write encoded data to the removable storage medium, and read encoded data from the removable storage medium, the cover comprising a distal end, a proximal end wherein the storage medium is inserted into the retention position at the proximal end, a midsection between the distal end and the proximal end, a plurality of mounting elements configured to mount the cover to the storage mechanism, wherein at least two mounting element are disposed near the proximal end and at least two mounting elements are disposed near the distal end, and at least four slots, the cover further comprising a top configured as planar member extending from the distal end to the proximal end and a first and second side each extending from the distal end to the proximal end and configured as planar members in physical communication with the top and disposed at an angle in the range of seventy degrees to one hundred-ten degrees to the top, and wherein each slot comprises a first slit that physically separates a midsection side from an end and a second slit at an angle in the range of seventy degrees to one hundred-ten degrees to the first slit and that physically separates the a portion of the top from a portion of a side;
physically isolate the midsection from the mounting elements with the slots; and
physically connect the midsection to an enclosure configured to supply power, cooling, and communications to the storage mechanism.

19. The method of claim 18, wherein the mounting elements are configured as mounting holes that accept a fastener that physically connects the cover to the storage mechanism.

20. The method of claim 19, wherein the mounting holes are threaded and accept a screw.
